(19) United States
(12) Patent Application Publication
(10) Pub. No.: US 2026/0215041 A1
(43) Pub. Date: Jul. 23, 2026

(54) LIGHT EMITTING DIODE (LED) DIES AND DEVICES WITH COMMON ANODE

(71) Applicant: Lumileds LLC, San Jose, CA (US)

(72) Inventors: Toni Lopez, Vaals (NL); Erik William Young, San Jose, CA (US)

(73) Assignee: Lumileds LLC, San Jose, CA (US)

(21) Appl. No.: 19/137,956

(22) PCT Filed: Nov. 29, 2023
(86) PCT No.: PCT/US2023/081541

§ 371 Date: Jun. 11, 2025

Related U.S. Application Data
(60) Provisional application No. 63/387,648, filed on Dec. 15, 2022.
(60) Provisional application No. 63/489,022, filed on Mar. 8, 2023.

(51) Int. Cl. H10H 20/832; H10H 20/01; H10H 20/816; H10H 20/821; H10H 20/825; H10H 20/857

(52) U.S. Cl. CPC H10H 20/832; H10H 20/01335; H10H 20/017; H10H 20/032; H10H 20/0364; H10H 20/816; H10H 20/821; H10H 20/825; H10H 20/857

(57) ABSTRACT

Light emitting diode (LED) arrays and dies and devices herein comprise: a plurality of pixels in electrical communication including a cathode per pixel and a common composite anode. Each pixel communicates to the common anode by a p-metal plug in a p-via, a p-metal layer, and p-contact materials.

### TECHNICAL FIELD

Embodiments of the disclosure generally relate to light emitting diodes (LEDs), dies, and devices with the same, and methods of manufacturing and using the same. More particularly, embodiments are directed to micro-light emitting diode devices that include a common anode.

### BACKGROUND

A light emitting diode (LED) is a semiconductor light source that emits visible light when current flows through it. LEDs combine a p-type semiconductor with an n-type semiconductor. LEDs commonly use a III-V group compound semiconductor. A III-V group compound semiconductor provides stable operation at a higher temperature than devices that use other semiconductors. The III-V group compound is typically formed on a substrate formed of sapphire aluminum oxide (Al₂O₃) or silicon carbide (SiC). For example, one or more III-nitride materials, such as GaN, can be epitaxially-grown on a substrate or wafer to prepare semiconductor layers. The substrate may remain as part of a final product, or may be removed during processing.

In-organic light emitting diodes (i-LEDs) have been widely used to create different types of displays, LED matrices and light engines including automotive adaptive headlights, augmented-, virtual-, mix-reality (AR/VR/MR) headsets, smart glasses and displays for mobile phones, smart watches, monitors and TVs. The individual LED pixels in these architectures could have an area of few square millimeters down to few square micrometers depending on the matrix or display size and its pixel per inch requirements. One common approach is to create a monolithic array of LED pixels on an epitaxial (EPI) wafer and later transfer and possibly hybridize these LED arrays to a backplane to control individual pixels.

One embodiment of such monolithic arrays utilizes metal (e.g., Al-based or Ag-based) side-contacts. These side contacts serve as an electrical cathode for each pixel and also provide reflective sidewalls in between the pixels to reduce light scattering and propagation in lateral directions. With this geometry, a metal grid is created in between pixels of an LED display or matrix. Such side contacts typically extend deep into a bottom of a trench in between the pixels formed by etching and/or segmenting the semiconductor (epitaxial) layers, and reach a surface of the substrate. Deep side contacts can be used to ensure low sheet and contact resistance for cathode contacts, and to optically separate each LED pixel so that there is not optical crosstalk, thereby maximize optical contrast.

With some monolithic LED architectures, a substrate, sometimes referred to as a “growth” substrate (e.g., sapphire, silicon), may be removed after an array is integrated with a backplane controller combination. This offers multiple advantages such as enhanced light extraction and beam profiling. One typical approach to remove a substrate, for example a sapphire substrate, is by a laser lift-off process (LLO) where a laser beam (UV laser in the case of sapphire substrate) is used to detach the substrate from the epitaxial layers (which were grown on the substrate). With such architectures, a challenge is that a trench surface interface to the epitaxial layers must be a metal to form contact. Metals are usually poor optical reflectors and hence extraction efficiency (ExE) is limited by severe absorption in the cavity.

There is a need for improving and/or maximizing optical efficiency in designs of LEDs, including micro-LEDs.

### SUMMARY

Light emitting diode (LED) arrays and dies and devices herein comprise: a plurality of pixels in electrical communication including a cathode per pixel and a common composite anode. Each pixel communicates to the common anode by a p-metal plug in a p-via, a p-metal layer, and p-contact materials.

In an aspect, a light emitting diode (LED) die comprises: a plurality of pixels each having a sidewall and a top surface, and being defined by a mesa of semiconductor layers, each of the mesas including an n-type layer, an active region, and a p-type layer; a current spreading layer on the p-type layer of each of the pixels; a plurality of junction spacers comprising a spacer dielectric material conformal to the sidewall of each of the pixels; a first dielectric material on a portion of the current spreading layer of each of the pixels; a plurality of e-vias defined by e-via sidewalls of the first dielectric material, a guard layer on the first dielectric material and disposed in each of the e-vias in contact with the current spreading layer; a second dielectric material disposed on a portion of the guard layer of each of the pixels, insulating the n-type layers and the p-type layers of each of the pixels; a plurality of p-vias defined by p-via sidewalls of the second dielectric material, a p-metal material plug disposed in each of the p-vias in contact with the guard layer; a plurality of n-vias each defined by an n-via spacer sidewall of the spacer dielectric material that extend from a depth of the n-type layer of each of the pixels to an n-metal layer, an n-contact material disposed in each of the n-vias in contact with the n-type layer of each of the pixels; for each pixel, the n-metal layer being disposed on surfaces of the n-contact material, the n-via spacer sidewalls, and the second dielectric material, and in contact with a cathode; a plurality of p-contact materials disposed in trenches between the mesas; for each pixel, a p-metal layer being disposed on the p-metal material plug, the second dielectric material, the junction spacers, and the p-contact materials; a passivation layer comprising a passivation dielectric material disposed on the p-metal layer and optionally a portion of the n-metal layer of each of the pixels, and a portion of the second dielectric material, insulating the cathode of each of the pixels and the p-contact materials; and a common anode in communication with each of the p-contact materials.

Another aspect is a method of manufacturing a light emitting diode (LED) die comprising: depositing a plurality of semiconductor layers including an n-type layer, an active region, and a p-type layer on a substrate; depositing a current spreading layer on the plurality of semiconductor layers; depositing a first hard mask layer comprising a first dielectric material on the current spreading layer; patterning the first hard mask layer to prepare e-vias defined by e-via sidewalls of the first dielectric material; depositing a guard layer on the first hard mask layer and in the e-vias; depositing a second hard mask layer comprising a second dielectric material on the guard layer; etching the substrate to form first trenches and expose positions of the current spreading layer; prepare inner spacers on sidewalls of the first trenches; etching the first trenches further to form extended trenches between mesas of the semiconductor layers and an n-via extending into each of the mesas; depositing a spacer dielectric material conformal to sidewalls of the extended trenches and the n-vias to prepare trench spacers and n-via spacer sidewalls, respectively; etching the second hard mask layer to prepare p-vias defined by p-via sidewalls of the second dielectric material; depositing a first electrode material in the extended trenches, the p-vias, and the n-vias, and planarizing the first electrode material to prepare p-contact materials, p-metal material plugs, n-contact materials; depositing a second electrode material on the substrate and patterning to prepare an n-metal layer in communication with the n-contact materials, and a p-metal layer in communication with the p-contact materials; preparing a common anode from a plurality of the p-contact materials, the common anode surrounding a plurality of pixels defined by the mesas; depositing a passivation layer comprising a passivation dielectric material on the substrate and patterning to dispose the passivation layer on the p-metal layers, optionally on a portion of the n-metal layers, a portion of the second dielectric material, insulating the n-type layer and p-type layer of each of the pixels; and preparing a cathode on each of the mesas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1A illustrates a cross-sectional view of a stack of semiconductor layers, a current spreading layer, and a first hard mask layer (of a first dielectric layer) deposited on a substrate according to one or more embodiments;

FIG. 1B illustrates a cross-sectional view of the stack after an operation in the manufacture of LEDs and their dies and devices according to one or more embodiments;

FIG. 1C illustrates a cross-sectional view of the stack after an operation in the manufacture of a LEDs and their dies and devices according to one or more embodiments;

FIG. 1D illustrates a cross-sectional view of the stack after an operation in the manufacture of LEDs and their dies and devices according to one or more embodiments;

FIG. 1E illustrates a cross-sectional view of the stack after an operation in the manufacture of LEDs and their dies and devices according to one or more embodiments;

FIG. IF illustrates a cross-sectional view of the stack after an operation in the manufacture of LEDs and their dies and devices according to one or more embodiments;

FIG. 1G illustrates a cross-sectional view of the stack after an operation in the manufacture of LEDs and their dies and devices according to one or more embodiments;

FIG. 1H illustrates a cross-sectional view of the stack after an operation in the manufacture of LEDs and their dies and devices according to one or more embodiments;

FIG. 1I illustrates a cross-sectional view of a light emitting diode (LED) after a finishing operation according to one or more embodiments;

FIG. 2 illustrates a cross-sectional view of a LED passing through the n-via, p-vias, and e-vias according to one or more embodiments;

FIG. 3 illustrates a cross-sectional view of a LED passing through the n-via, p-vias, and e-vias according to one or more embodiments;

FIG. 4 illustrates a top view of an LED according to the embodiment of FIG. 3, the cross-section of which is on a diagonal with respect to FIG. 4;

FIG. 5 illustrates a top view of an LED array or die including the embodiment of FIGS. 3 and 4;

FIG. 6 illustrates a top view of an LED according to one or more embodiments;

FIG. 7 illustrates a top view of an LED array or die including the embodiment of FIG. 6;

FIG. 8 illustrates a cross-sectional view of a LED passing through the n-via, p-via, and e-via according to one or more embodiments;

FIG. 9 illustrates a process flow diagram for a method of manufacture according to one or more embodiments;

FIG. 10 schematically illustrates an exemplary display system comprising uLED devices according to embodiments herein;

FIG. 11 shows a block diagram of a visualization system according to one or more embodiments; and

FIG. 12 shows a cross-sectional view of a light emitting diode (LED) after a finishing operation according to one or more embodiments.

To facilitate understanding, identical reference numerals have been used, where possible, to designate identical elements that are common to the figures. The figures are not drawn to scale. For example, the heights and widths of the mesas are not drawn to scale.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN and alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed are also performed on an underlayer formed on the substrate, and the term “substrate surface” is intended to include such underlayer as the context indicates. Thus for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Reference to a micro-LED (uLED) means a light emitting diode having one or more characteristic dimensions (e.g., height, width, depth, thickness, etc. dimensions) of less than 100 micrometers. In one or embodiments, one or more dimensions of height, width, depth, thickness have values in a range of 2 to 25 micrometers.

For some architectures of monolithic arrays that utilize pixels defined by mesas of layers of semiconductor materials (including an n-type layer, an active region, and a p-type layer) and metal (e.g., Al-based or Ag-based) side-contacts, in order to electrically isolate p-type and n-type layers, a dielectric layer (e.g., a junction spacer) is typically used at trench sidewalls covering active region edges. Such a spacer typically extends a thickness of the semiconductor layers sufficient to etch away the active region so as to access highly doped layers of the epi. This usually corresponds to a small fraction of the epi thickness (e.g. ⅙).

Dies and devices herein avoid the use of lateral metal-semiconductor contacts at the metal trenches. Metal trenches are typically used to facilitate high contrast, however, a dielectric interposer is introduced to minimize light interaction with the metal trench, thereby reducing optical absorption. Pixels herein arrange a cathode (or N-contact) by forming an n-via in the pixel's inner area (preferentially center region), and an e-via and one or more p-vias accordingly. In one or more embodiments, a composite of a p-via nested in an e-via may be displaced toward the pixel corners. By way of a non-limiting example, positioning the n-via in a center of the pixel allows a simple interconnects arrangement for a common anode architecture, which includes a discontinuous bonding layer (or p-metal layer).

Advantageously, die and epitaxial layers (epi) layouts herein create a composite common anode contact for monolithic LED arrays, including micro-LED arrays, mini-LED arrays, and other LED arrays, with increased optically isolated metal trenches. The pixel architecture with composite common anode arrangement is an alternative to common cathode architectures. The common anode is a composite trench for optical isolation of lateral metal trenches. N-type CMOS circuitry is suitable for common anode current driving. The common anodes improve optical performance of monolithically integrated micro-LED, mini-LED, and other LED arrays, and simplifies driver electronics with minimal impact on full voltage (Vf) and internal quantum efficiency (IQE) droop. The methods and embodiments herein are applicable to both phosphor-converted and direct-color LEDs where each individual pixel has an area ranging from a few hundred square micrometers (micro-LEDs) to square millimeters (conventional LEDs).

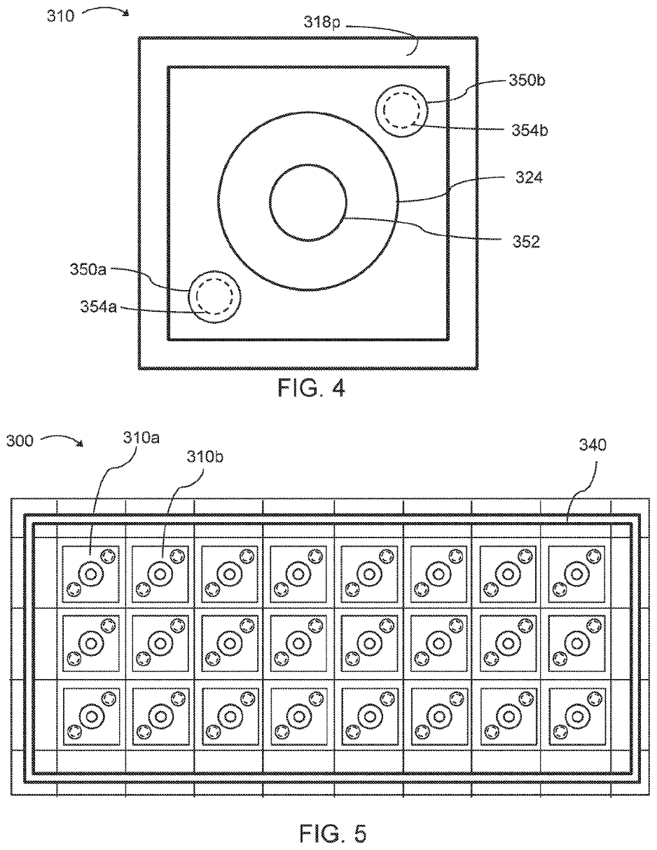

With respect to an embodiment of an n-via in the pixel's central region, and a composite of a p-via nested in an e-via displaced toward the pixel corners (e.g., FIG. 4), flux gains and electrical impacts were analyzed by simulation. With respect to flux gains, optical isolation indicates optical flux gains (ExE) close to 19%, for extraction in air. Package efficiency gains are also expected for phosphor-converted (pc) LEDs. As to electrical, minimum Vf and IQE penalties are achieved with two composites of the p-via nested in the e-via displaced toward the pixel corners, as compared to positioning in a single comer which could experience high current crowding injection through the active region. Additional electrical benefits are expected from the driver side. That is, pMOS technology can be avoided with the associated level shifter circuitry. Consequently, driver complexity can be largely reduced leading to lower cost and/or improved efficiency. The latter benefits from the use of nMOS technology, which offers lower on-resistance transistors.

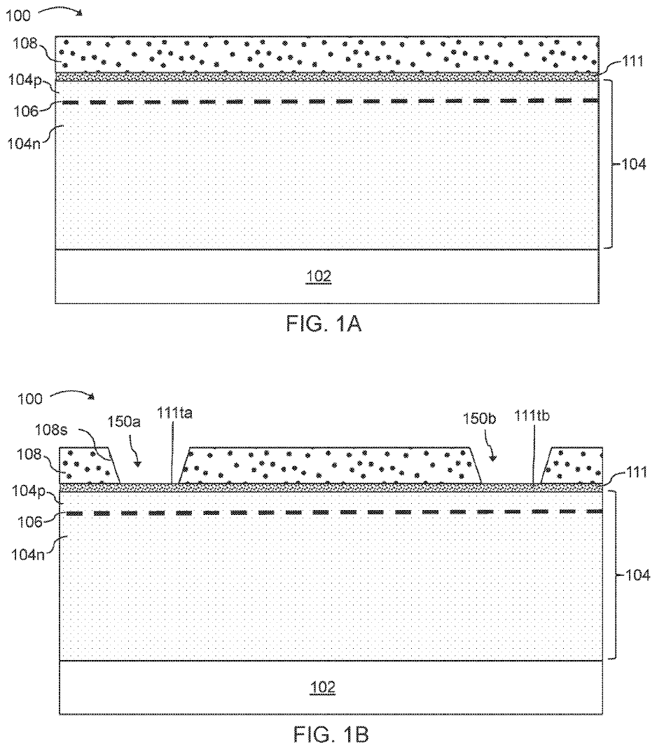

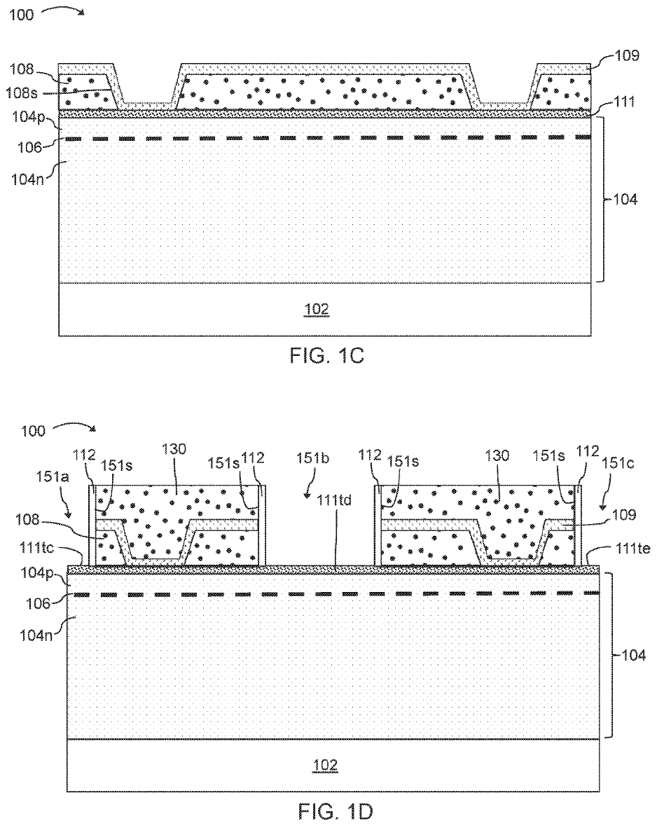

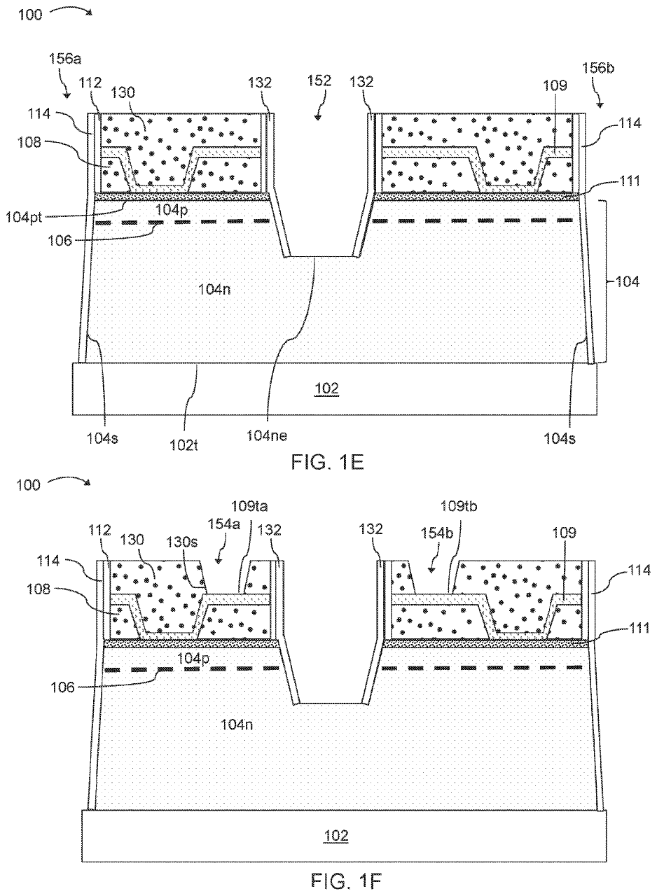

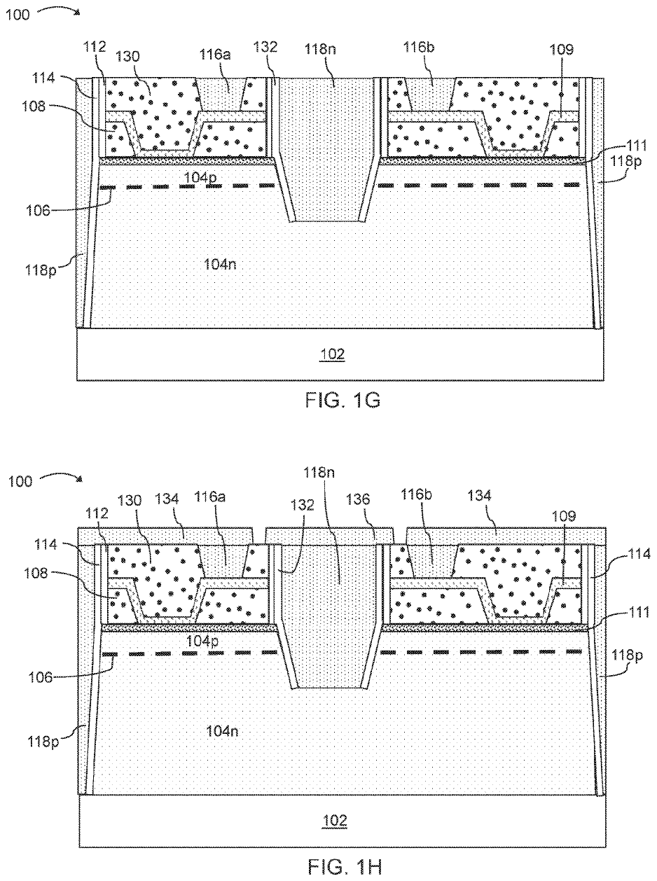

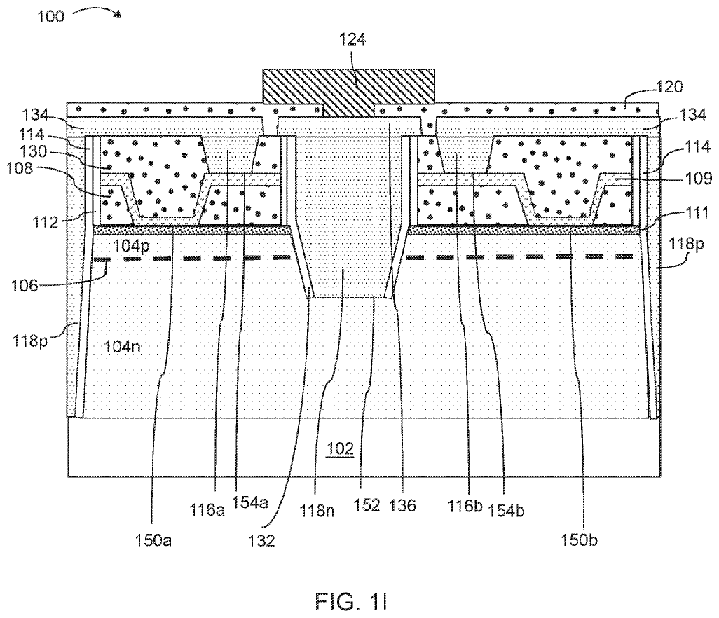

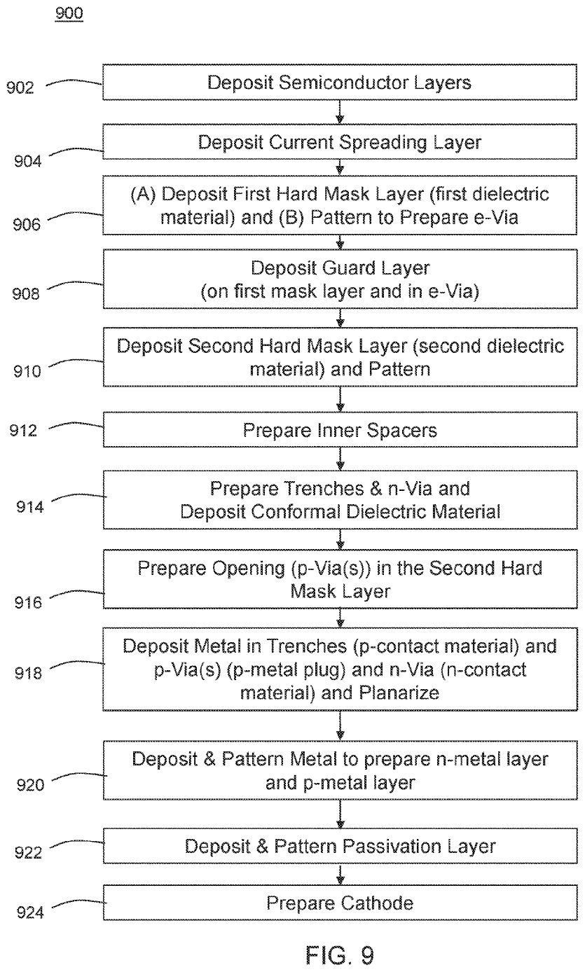

With reference to FIG. 1A to II and FIG. 9, the following is a description of manufacture of LEDs, LED dies, and LED devices according to embodiments of this disclosure. FIGS. 1A to 1I are cross-sectional views as the view passes through the area where any n-via, p-via, and e-via are being prepared. The manufacture involves a series of operations 900 of FIG. 9 conducted on a monolithic array 100, which is shown for an excerpted portion of the array detailing a pixel. FIG. 1A is a cross-sectional view of a stack of semiconductor layers 104, a current spreading layer 111, and a first hard mask layer 108 (of a first dielectric layer) deposited on a substrate 102 during operations 902 and 904 and 906(A) in the manufacture of a LED device according to one or more embodiments. With reference to FIG. 1A, the semiconductor layers 104 are grown on the substrate 102. The semiconductor layers 104 according to one or more embodiments comprise epitaxial layers, III-nitride layers or epitaxial III-nitride layers.

The substrate may be any substrate known to one of skill in the art. In one or more embodiments, the substrate comprises one or more of sapphire, silicon carbide, silicon (Si), quartz, magnesium oxide (MgO), zinc oxide (ZnO), spinel, and the like. In one or more embodiments, the substrate is not patterned prior to the growth of the epitaxial layer(s). Thus, in some embodiments, the substrate is not patterned and can be considered to be flat or substantially flat. In other embodiments, the substrate is patterned, e.g. patterned sapphire substrate (PSS).

In one or more embodiments, the semiconductor layers 104 comprise a III-nitride material, and in specific embodiments epitaxial III-nitride material. In some embodiments, the III-nitride material comprises one or more of gallium (Ga), aluminum (Al), and indium (In). Thus, in some embodiments, the semiconductor layers 104 comprises one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like. In one or more specific embodiments, the semiconductor layers 104 comprises a p-type layer, an active region, and an n-type layer. In one or more embodiments, the semiconductor layers 104 comprise a III-nitride material, and in specific embodiments epitaxial III-nitride material. In some embodiments, the III-nitride material comprises one or more of gallium (Ga), aluminum (Al), and indium (In). Thus, in some embodiments, the semiconductor layers 104 comprises one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like.

In one or more embodiments, the substrate 102 is placed in a metalorganic vapor-phase epitaxy (MOVPE) reactor for epitaxy of LED device layers to grow the semiconductor layers 104.

In one or more embodiments, the semiconductor layers 104 comprise a stack of undoped III-nitride material and doped III-nitride material. The III-nitride materials may be doped with one or more of silicon (Si), oxygen (O), boron (B), phosphorus (P), germanium (Ge), manganese (Mn), or magnesium (Mg) depending upon whether p-type or n-type III-nitride material is needed. In specific embodiments, the semiconductor layers 104 comprise an n-type layer 104n, an active region 106 and a p-type layer 104p.

In one or more embodiments, the semiconductor layers 104 have a combined thickness in a range of from about 2 μm to about 10 μm, including a range of from about 2 μm to about 9 μm, 2 μm to about 8 μm, 2 μm to about 7 μm, 2 μm to about 6 pm, 2 μm to about 5 μm, 2 μm to about 4 μm, 2 μm to about 3 μm, 3 μm to about 10 μm, 3 μm to about 9 μm, 3 μm to about 8 μm, 3 μm to about 7 μm, 3 μm to about 6 μm, 3 μm to about 5 μm, 3 μm to about 4 μm, 4 μm to about 10 μm, 4 μm to about 9 μm, 4 μm to about 8 μm, 4 μm to about 7 μm, 4 μm to about 6 μm, 4 μm to about 5 μm, 5 μm to about 10 μm, 5 μm to about 9 μm, 5 μm to about 8 μm, 5 μm to about 7 μm, 5 μm to about 6 μm, 6 μm to about 10 μm, 6 μm to about 9 μm, 6 μm to about 8 μm, 6 μm to about 7 μm, 7 μm to about 10 μm, 7 μm to about 9 μm, or 7 μm to about 8 μm.

In one or more embodiments, the active region 106 is formed between the n-type layer 104n and the p-type layer 104p. The active region 106 may comprise any appropriate materials known to one of skill in the art. In one or more embodiments, the active region 106 is comprised of a III-nitride material multiple quantum wells (MQW), and a III-nitride electron blocking layer.

In one or more embodiments, a current spreading contact layer 111 and a first hard mask layer 108 are deposited on the p-type layer 104p. As shown, the current spreading contact layer 111 is deposited on the p-type layer 104p and the hard mask layer 108 is on the current spreading contact layer 111. In some embodiments, the current spreading contact layer 111 is deposited directly on the p-type layer 104p. In other embodiments, not illustrated, there may be one or more additional layer between the p-type layer 104p and the current spreading contact layer 111. In some embodiments, the hard mask layer 108 is deposited directly on the current spreading contact layer 111. In other embodiments, not illustrated, there may be one or more additional layers between the hard mask layer 108 and the current spreading contact layer 111. The hard mask layer 108 and the current spreading contact layer 111 may be deposited by any appropriate technique known to the skilled artisan. In one or more embodiments, the hard mask layer 108 and the current spreading contact layer 111 are deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g. a metal, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e. two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition (CVD)” refers to a process in which films of materials are deposited from the vapor phase by decomposition of chemicals on a substrate surface. In CVD, a substrate surface is exposed to precursors and/or co-reagents simultaneous or substantially simultaneously. As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. A PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g. a thin film on a substrate. Similarly to a thermal ALD process, a purge step maybe conducted between the delivery of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, the hard mask layer 108 may be fabricated using materials and patterning techniques which are known in the art. In some embodiments, the hard mask layer 108 comprises a metallic or dielectric material. Suitable dielectric materials include, but are not limited to, silicon oxide (SiO), silicon nitride (SiN), silicon carbide (SiC), aluminum oxide (AIOR), aluminum nitride (AIN) and combinations thereof. The skilled artisan will recognize that the use of formulas like SiO, to represent silicon oxide, does not imply any particular stoichiometric relationship between the elements. The formula merely identifies the primary elements of the film.

In one or more embodiments, the current spreading contact layer 111 may comprise any suitable metal known to one of skill in the art. In one or more embodiments, the current spreading layer 111 comprises indium tin oxide (ITO) and/or indium zinc oxide (IZO).

FIG. 1B is a cross-sectional view of the stack after an operation 906(B) of FIG. 9 in the manufacture of a LEDs and their dies and devices according to one or more embodiments. With reference to FIG. 1B, the first hard mask layer 108 and current spreading layer 111 are patterned to form openings in the first hard mask layer 108 to prepare e-vias 150a and 150b defined by e-via sidewalls 108s of the first dielectric material and exposed top surfaces 111ta and 111tb of portions of the current spreading layer 111.

In one or more embodiments, the first hard mask layer 108 is patterned according to any appropriate patterning technique known to one of skill in the art. In one or more embodiments, the first hard mask layer 108 is patterned by etching. According to one or more embodiments, conventional masking, wet etching and/or dry etching processes can be used to pattern the hard mask layer 108.

In other embodiments, a pattern is transferred to the first hard mask layer 108 using nanoimprint lithography. In one or more embodiments, the substrate 102 is etched in a reactive ion etching (RIE) tool using conditions that etch the first hard mask layer 108 efficiently but etch the p-type layer 104p very slowly or not at all. In other words, the etching is selective to the first hard mask layer 108 over the current spreading layer 111. In a patterning step, it is understood that masking techniques may be used to achieve a desired pattern.

FIG. 1C is a cross-sectional view of the stack after an operation 908 of FIG. 9 in the manufacture of LEDs and their dies and devices according to one or more embodiments. With reference to FIG. 1C, a guard layer 109 is deposited on the first hard mask layer 108 and in the e-vias 150a and 150b. As shown in the embodiment of FIG. 1C, the guard layer 109 is substantially conformal to the e-via openings (as numbered 150a and 150b in FIG. 1B). As used herein, a layer which is “substantially conformal” refers to a layer where the thickness is about the same throughout (e.g., on the first hard mask layer 108, on the sidewalls 108s and on the bottom of the e-via opening, namely, the exposed surfaces of portions of the current spreading layer 111ta and 111tb (as numbered in FIG. 1B)).

As used herein, a layer which is substantially conformal varies in thickness by less than or equal to about 5%, 2%, 1% or 0.5%.

Without intending to be bound by theory, according to one or more embodiments, the guard layer 109 may prevent metal ions from electrode materials from migrating and shorting the device 100.

FIG. 1D is a cross-sectional view of the stack after operations 910 and 912 in the manufacture of LEDs and their dies and devices according to one or more embodiments. With reference to FIG. 1D, a second hard mask layer 130 of a second dielectric material is deposited on the substrate on the guard layer 109, and thereafter is etched to prepare first trenches 151a, 151b, and 151c and expose portions of the current spreading layer 111tc, 111td, and 111te. Material to prepare the inner spacers 112 is deposited on the substrate. The inner spacers 112 may comprise any appropriate material known to one of skill in the art. In one or more embodiments, the inner spacers 112 comprise a dielectric material. Deposition of the material that forms the inner spacers is typically done conformally to the substrate surface, followed by etching to achieve inner spacers on sidewalls 151s of the first trenches but not on the exposed surfaces 111tc, 111td, and 111te of the current spreading layer 111.

As used herein, the term “dielectric” refers to an electrical insulator material that can be polarized by an applied electric field. In one or more embodiments, the inner spacers 112 include, but are not limited to, oxides, e.g., silicon oxide (SiO₂), aluminum oxide (Al₂O₃), nitrides, e.g., silicon nitride (Si₃N₄). In one or more embodiments, the dielectric inner spacers 112 comprise silicon nitride (Si₃N₄). In other embodiments, the inner spacers 112 comprise silicon oxide (SiO₂). In some embodiments, the inner spacers 112 composition is non-stoichiometric relative to the ideal molecular formula. For example, in some embodiments, the dielectric layer includes, but is not limited to, oxides (e.g., silicon oxide, aluminum oxide), nitrides (e.g., silicon nitride (SiN)), oxycarbides (e.g. silicon oxycarbide (SiOC)), and oxynitrocarbides (e.g. silicon oxycarbonitride (SiNCO)).

In some embodiments, the inner spacers 112 may be a distributed Bragg reflector (DBR). As used herein, a “distributed Bragg reflector” refers to a structure (e.g. a mirror) formed from a multilayer stack of alternating thin film materials with varying refractive index, for example high-index and low-index films.

In one or more embodiments, the inner spacers 112 are deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

In one or more embodiments, the inner spacers 112 have a thickness in a range of from about 200 nm to about 1 μm, for example, about 300 nm to about 1 μm, about 400 nm to about 1 μm, about 500 nm to about 1 μm, about 600 nm to about 1 μm, about 700 nm to about 1 μm, about 800 nm to about 1 μm, about 500 nm to about 1 μm, about 200 nm to about 900 nm, 300 nm to about 900 nm, about 400 nm to about 900 nm, about 500 nm to about 900 nm, about 600 nm to about 900 nm, about 700 nm to about 900 nm, about 800 nm to about 900 nm, about 200 nm to about 800 nm, 300 nm to about 800 nm, about 400 nm to about 800 nm, about 500 nm to about 800 nm, about 600 nm to about 800 nm, about 700 nm to about 800 nm, about 200 nm to about 700 nm, about 300 nm to about 700 nm, about 400 nm to about 700 nm, about 500 nm to about 700 nm, about 600 nm to about 700 nm, about 200 nm to about 600 nm, about 300 nm to about 600 nm, about 400 nm to about 600 nm, about 500 nm to about 600 nm, about 200 nm to about 500 nm, about 300 nm to about 500 nm, about 300 nm to about 400 nm, about 200 nm to about 400 nm, or about 300 nm to about 400 nm.

FIG. 1E is a cross-sectional view of the stack after operation 914 of FIG. 9 in the manufacture of LEDs and their dies and devices according to one or more embodiments. With reference to FIG. 1E, the semiconductor layers 104 are etched to form a mesa, having a mesa sidewall 104s defining a width and a height from a top edge 102t of the substrate 102 to a top surface 104pt of the p-type layer 104p. In the embodiment illustrated in FIG. IE, the mesa has a trench 156a and 156b that separates it from other mesas of the die or array. The semiconductor layers 104 are also etched to form an n-via 152. Trench spacers (or outer spacers) 114 are deposited on sidewalls of the trenches 156a and 156b, and n-via spacer sidewall 132 is deposited on sidewall of the n-via 152. The trench spacers 114 n-via spacer sidewall 132 may comprise any appropriate material known to one of skill in the art. In one or more embodiments, the trench spacers 114 and/or the n-via spacer sidewall 132 comprise a spacer dielectric material. The dielectric material insulates the sidewall of the mesa 104s (e.g. sidewall of the p-type layer 104p, the active region 106, and the n-type layer 104n) from metal that is deposited in the n-via 152 and the trenches 156a and 156 b, as described with respect to FIG. 1G. Deposition of the material that forms the trench spacers 114 and n-via spacer sidewall 132 is typically done conformally to the substrate surface, followed by etching to achieve outer spacers on the sidewalls but not the bottom of the respective trench (the substrate top surface 102t) or n-via (exposed surface 104ne of the n-type layer 104n).

In one or more embodiments, the trench spacers 114 and the n-via spacer sidewall 132 may independently be oxides, e.g., silicon oxide (SiO₂), aluminum oxide (Al₂O₃), nitrides, e.g., silicon nitride (Si₃N₄). In one or more embodiments, the trench spacer 114 and/or the n-via spacer sidewall 132 comprises silicon nitride (Si₃N₄). In other embodiments, the trench spacer 114 and/or the n-via spacer sidewall 132 comprises silicon oxide (SiO₂). In some embodiments, the trench spacers 114 may be a distributed Bragg reflector (DBR).

In one or more embodiments, the trench spacers 114 and the n-via spacer sidewall 132 are deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

FIG. IF is a cross-sectional view of the stack after an operation 916 of FIG. 9 in the manufacture of a LEDs and their dies and devices according to one or more embodiments. With reference to FIG. 1F, the second hard mask layer 130 is patterned to form openings in the second hard mask layer 130 to prepare p-vias 154a and 154b defined by p-via sidewalls 130s of the second dielectric material and exposed top surfaces 109ta and 109tb of portions of the guard layer 109.

In one or more embodiments, the second hard mask layer 130 is patterned according to any appropriate patterning technique known to one of skill in the art. In one or more embodiments, the second hard mask layer 130 is patterned by etching. According to one or more embodiments, conventional masking, wet etching and/or dry etching processes can be used to pattern the second hard mask layer 130.

In other embodiments, a pattern is transferred to the second hard mask layer 130 using nanoimprint lithography. In one or more embodiments, the substrate 102 is etched in a reactive ion etching (RIE) tool using conditions that etch the second hard mask layer 130 efficiently but etch the guard layer 109 very slowly or not at all. In other words, the etching is selective to the second hard mask layer 130 over the guard layer 109. In a patterning step, it is understood that masking techniques may be used to achieve a desired pattern.

FIG. 1G is a cross-sectional view of the stack after operation of 918 of FIG. 9 in the manufacture of LEDs and their dies and devices according to one or more embodiments. With reference to FIG. 1G, a first electrode metal is deposited on the substrate, including in the p-vias 154a, 154b (as shown in FIG. 1F), in the trenches 156a, 156b (as shown in FIG. 1E), and in the n-via 152 (as shown in FIG. 1E). The electrode metal can comprise any appropriate material known to the skilled artisan. In one or more embodiments, the electrode metal comprises copper, and the electrode metal material is deposited by electrochemical deposition (ECD) of the copper.

The electrode material is planarized, etched, or polished to yield an n-contact material 118n, a p-metal material plugs 116a, 116b, a p-contact material 118p in a final product. As used herein, the term “planarized” refers to a process of smoothing surfaces and includes, but is not limited to, chemical mechanical polishing/planarization (CMP), etching, and the like.

FIG. 1H is a cross-sectional view of the stack after operation 920 of FIG. 9 in the manufacture of LEDs and their dies and devices according to one or more embodiments. With reference to FIG. 1H, a second electrode metal is deposited on the substrate, and patterned to prepare an n-metal layer 136 and a p-metal layer 134, which are separated. The second electrode metal is deposited on top surfaces of inner spacers 112, of the trench spacer 114, and of the second hard mask layer 130. The n-metal layer 136 is in communication with the n-contact material 118n, and the p-metal layer 134 in communication with the p-contact materials 118p and the p-metal material plugs 116a, 116b.

FIG. 1I is a cross-sectional view of the stack after operations 922 and 924 of FIG. 9 in the manufacture of LEDs and their dies and devices according to one or more embodiments. With reference to FIG. 1I, a passivation layer 120 is deposited on the substrate and in between the n-metal layer 136 and the p-metal layer 134. In some embodiments, the passivation layer 120 is deposited directly on the planarized n-contact material 118n, the planarized p-metal material plugs 116a, 116b, and the planarized p-contact material 118p. In other embodiments, there may be one or more additional layers between the passivation layer 120 and the planarized n-contact material 118n, the planarized p-metal material plug 118p, and the planarized p-contact material 118p. In some embodiments, the passivation material comprises the same material as the first hard mask layer 108 or the second hard mask layer 130. In other embodiments, the passivation layer 120 comprises a material distinct from either the first hard mask layer 108 or the second hard mask layer 130.

In one or more embodiments, the passivation layer 120 may be deposited by any suitable technique known to one of skill in the art. In one or more embodiments, the passivation layer 120 is deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

In one or more embodiments, the passivation layer 120 may be comprises by any suitable material known to one of skill in the art. In one or more embodiments, the passivation layer 120 comprises a dielectric material. Suitable dielectric materials include, but are not limited to, silicon oxide (SiO), silicon nitride (SiN), silicon carbide (SiC), aluminum oxide (AlOₓ), aluminum nitride (AlN) and combinations thereof.

The passivation layer 120 is patterned to form an opening, exposing a top surface of the n-metal layer 136. The passivation layer 120 may be patterned using any suitable technique known to one of skill in the art including, but not limited to, lithography, wet etching, or dry etching.

An under bump metallization (UBM) material forms a cathode 124, which is deposited in the openings of the passivation layer that exposes the top surface of the n-metal layer 136. As used herein, “under bump metallization (UBM)” refers to the metal layer which is required for connecting a die to a substrate with solder bumps for flip-chip packages. In one or more embodiments, the UBM material forms cathodes 124 that may be a patterned, thin-film stack of material that provides an electrical connection from the die to a solder bump, provides a barrier function to limit unwanted diffusion from the bump to the die, and provides a mechanical interconnection of the solder bump to the die through adhesion to the die passivation and attachment to a solder bump pad. The UBM material may comprise any suitable metal known to the skilled artisan. In one or more embodiments, the UBM material comprises gold (Au).

In one or more embodiments, under bump metallization (UBM) may be achieved by any technique known to one of skill in the art including, but not limited to, a dry vacuum sputter method combined with electroplating. In one or more embodiments, a dry vacuum sputter method combined with electroplating consists of multi-metal layers being sputtered in a high temperature evaporation system.

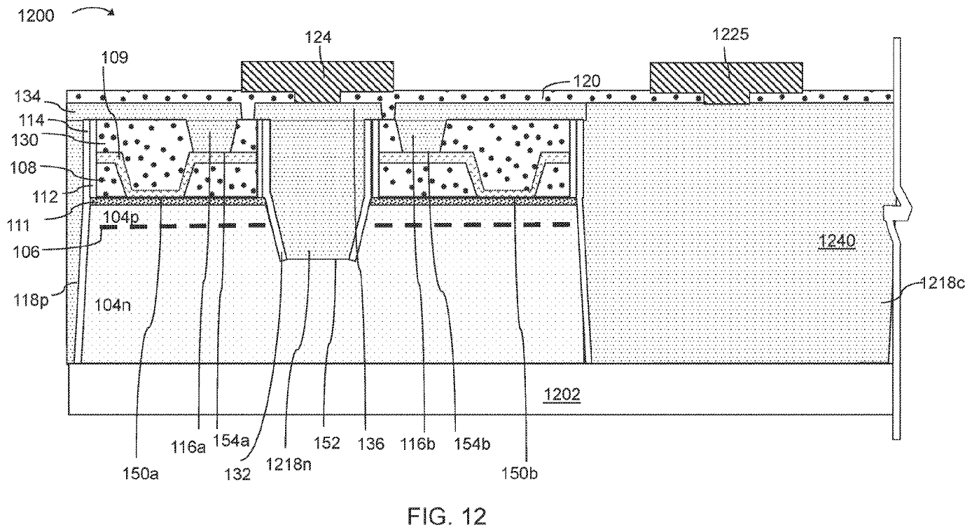

Dies and devices LEDs of FIG. 1I further include a common anode formed at an end of the array 100 as viewed in cross-section. The common anode comprises an electrode metal. A matrix of pixels is surrounded by the common anode. FIG. 12 shows a cross-sectional view of a light emitting diode (LED) after a finishing operation according to one or more embodiments, where a common anode 1240 comprising an electrode metal 1218c, typically a p metal, is shown on a substrate 1202 next to a pixel defined by mesas of the semiconductor materials and accompanying structure analogous to FIGS. 1A-1I, where like numbering refers to like structures. The common anode 1240 is typically a width of a plurality of pixels, and may comprise one or more anode pads 1225. The passivation layer 120 is in contact with the electrode metal 1218c. In one or more embodiments, the common anode is pixelated in that rather than preparing via openings as shown in FIG. 1E and IF, a portion of the mesas are etched to expose the top surface of the semiconductor layers. Thereafter, electrode material is deposited. The portion of the mesas that are etched to expose the top surface of the semiconductor layers are surrounded by electrode metal, and are inactive in that they do not generate light during use. Under bump metallization (UBM) material also provides one or more of the anode pads 1225 in contact with the common anode 1240, patterned analogously to the UBM material that forms the cathode 124.

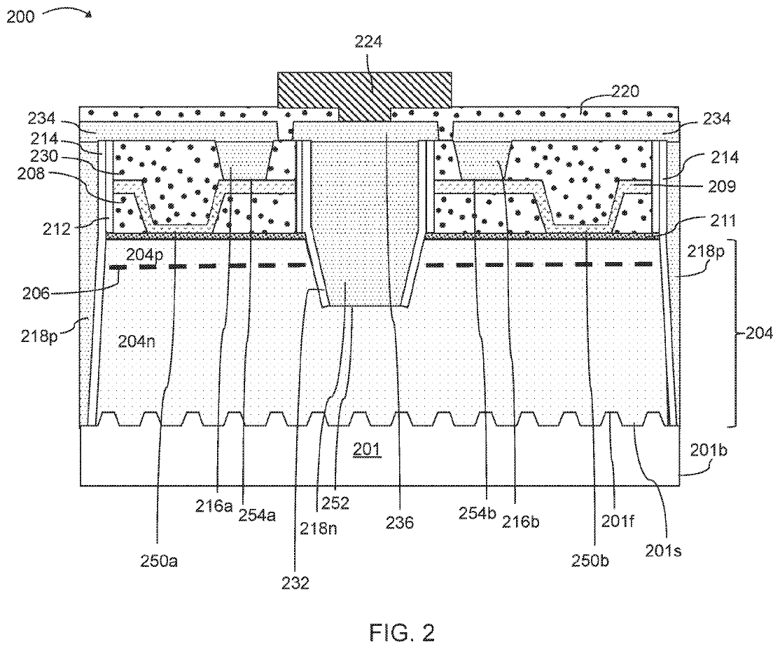

FIG. 2 illustrates a cross-sectional view of a LED passing through the n-via, p-vias, and e-vias according to one or more embodiments. The excerpted LED array 200 is analogous to that of FIG. 1I with the difference being a patterned substrate 201, e.g., a patterned sapphire substrate (PSS) is used for growth of the semiconductor layers 204, which yields a textured p-type layer 204b upon removal of substrate 201. In this embodiment, the n-via is nominally centered in the mesa, and the p-vias are off-set from the e-vias.

In FIG. 2, on the patterned substrate 201 is a stack of semiconductor layers 204 comprising an n-type layer 204n, an active region 206 and a p-type layer 204p. The patterned substrate may be created and/or prepared to comprise: a substrate body 201b, a plurality of integral features 201f protruding from the substrate body 201b, and a base surface 201s defined by spaces between the plurality of integral features 201f. The patterned substrate 201 may be created by etching, by wet and/or dry methods, an array pattern of holes through a mask into a substrate wafer. In one or more embodiments, the array pattern has a pitch designed to deliver a desired density of integral features. The patterned substrate may be designed to deliver a desired surface area ratio of the base surface versus the plurality of integral features. The devices herein may have an increased density of integral features relative to currently available devices. The ratio of the surface area of the base surface to the surface area of the plurality of integral features is greater than 0. In one or more embodiments, ratio of the surface area of the base surface to the surface area of the plurality of integral features is greater than 0 and less than or equal to 0.5, and all values and subranges therebetween. In one or more embodiments, the features comprise a shape, for example, a hemispherical shape, a triangular pyramidal shape, a quadrangular pyramidal shape, a hexagonal pyramid shape, a conical shape, and/or a semi-spherical shape.

A current spreading layer 211 is on the p-type layer 204p. N-via 252 comprises n-via spacer sidewall 232 which surrounds n-contact material 218n. A surface of the n-contact material 218n contacts the n-type layer 204n. An n-metal layer 236 is on a surface of the n-contact material 218n opposite that of the n-type layer 204n. A first hard mask layer 208 (of a first dielectric layer) is on the current spreading layer 211, and has been etched to form e-vias 250a and 250b. A guard layer 209 is on the first hard mask layer 208 and in the e-vias 250a and 250b. A second hard mask layer 230 (of a second dielectric layer the same or different from that of the first dielectric material) is on the guard layer 209, and has been etched to form p-vias 254a and 254b. In the p-vias 254a and 254b is p-metal material plugs 216a and 216b. On the p-metal material plugs 216a and 216b and portions of the second hard mask layer 230 is a p-metal layer 234 that provides communication between the p-type layer 204b, the guard layer 209, and the p-metal material plugs 216a and 216b to p-contact material 218p. Trench spacers (or outer spacers) 214 insulate the p-contact material 218p from the n-type layer 204n and the active region 206. Inner spacers 212 are adjacent to the n-via spacer sidewall 232 and the trench spacers (or outer spacers) 214.

A passivation layer 220 is on the p-metal layer 234 and is between the n-metal layer 236 and the p-metal layer 234. An under bump metallization (UBM) material forms a cathode 224 in contact with the n-metal layer 236.

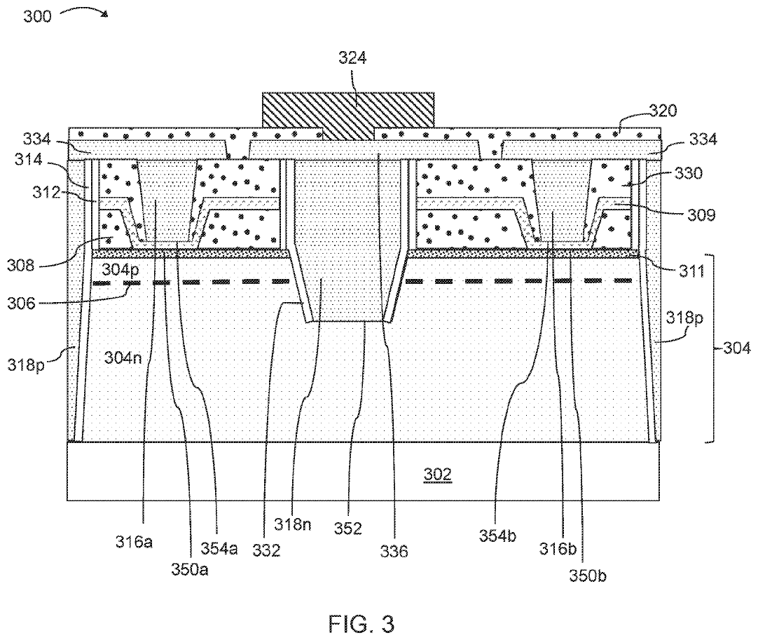

FIG. 3 illustrates a cross-sectional view of a LED passing through the n-via, p-vias, and e-vias according to one or more embodiments. The excerpted LED array 300 is analogous to that of FIG. 1I with the difference being the e-vias 350a, 350b and the p-vias 354a, 354b are respectively nested about a centered n-via 352. In this embodiment, the n-via is nominally centered in the mesa.

In FIG. 3, on the substrate 302 is a stack of semiconductor layers 304 comprising an n-type layer 304n, an active region 306 and a p-type layer 304p. A current spreading layer 311 is on the p-type layer 304 p. N-via 352 comprises n-via spacer sidewall 332 which surrounds n-contact material 318n. A surface of the n-contact material 318n contacts the n-type layer 304n. An n-metal layer 336 is on a surface of the n-contact material 318n opposite that of the n-type layer 304n. A first hard mask layer 308 (of a first dielectric layer) is on the current spreading layer 311, and has been etched to form e-vias 350a and 350b. A guard layer 309 is on the first hard mask layer 308 and in portions of the e-vias 350a and 350b on their sidewalls. A second hard mask layer 330 (of a second dielectric layer the same or different from that of the first dielectric material) is on the guard layer 309, and has been etched to form p-vias 354a and 354b nested in the e-vias 350a and 350b such that a bottom surface of each p-via 354a and 354b contacts a top surface of the guard layer 309. In the p-vias 354a and 354b is p-metal material plugs 316a and 316b. On the p-metal material plugs 316a and 316b and portions of the second hard mask layer 330 is a p-metal layer 334 that provides communication between the p-type layer 304b, the guard layer 309, and the p-metal material plugs 316a and 316b to p-contact material 318p. Trench spacers (or outer spacers) 314 insulate the p-contact material 318p from the n-type layer 304n and the active region 306. Inner spacers 312 are adjacent to the n-via spacer sidewall 332 and the trench spacers (or outer spacers) 314.

A passivation layer 320 is on the p-metal layer 334 and is between the n-metal layer 336 and the p-metal layer 334. An under bump metallization (UBM) material forms a cathode 324 in contact with the n-metal layer 336.

FIG. 4 illustrates a top view of the excerpted LED array according to the embodiment of FIG. 3, the cross-section of which is on a diagonal with respect to FIG. 4. FIG. 5 illustrates a top view of an LED array or die including the embodiment of FIGS. 3 and 4. The top view of FIG. 4 depicts a uLED 310 comprising the n-via 520 centered in the uLED 310 and a cathode 324 centered over the n-via 352. The e-vias 350a, 350b are on either side of the n-via 352. In the e-vias 350a, 350b are nested p-vias 354a, 354b. The p-contact material 318p surrounds the uLED 310. In the top view of FIG. 5 of an array 300, a plurality of uLEDs 310 a, 310 b as exemplified, are in an array of 8×3 as an example. In one or more embodiments, the arrays are on the order of hundreds to thousands and more. The plurality of uLEDs 310a, 310b, etc are surrounded by a common anode 340.

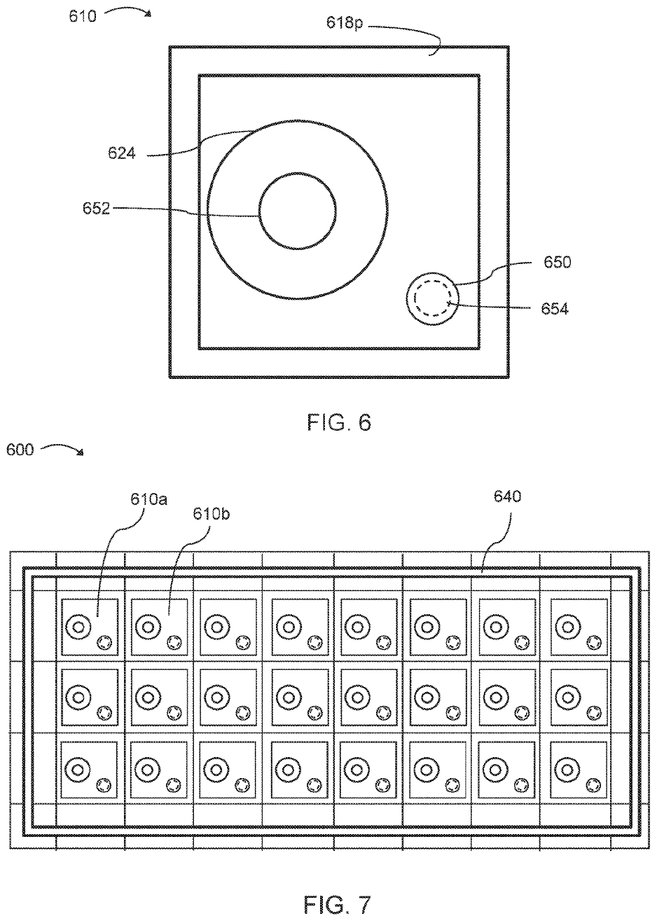

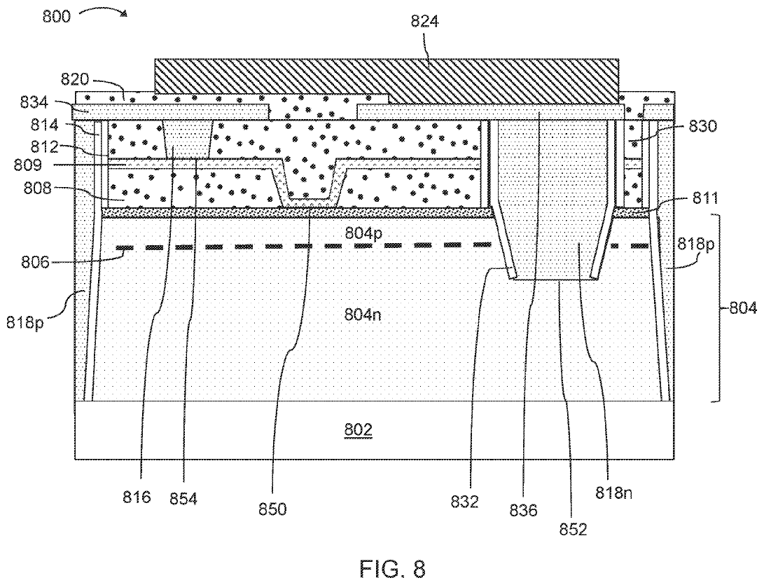

FIG. 6 illustrates a top view of an excerpted LED array according to one or more embodiments. The top view of FIG. 6 depicts a uLED 610 comprising one e-via 650 and p-via 654 nested composite adjacent to an off-centered n-via 652, over which a cathode 624 is centered. P-contact material 618p surrounds the uLED 310. FIG. 7 illustrates a top view of an LED array or die 600 including a plurality of uLEDs 610a, 610b as exemplified, according to the embodiment of FIG. 6, which are in an of 8×3 as an example. In one or more embodiments, the arrays are on the order of hundreds to thousands and more. The plurality of uLEDs 610a, 610b, etc are surrounded by a common anode 640.

FIG. 8 illustrates a cross-sectional view of a LED passing through the n-via, p-via, and e-via according to one or more embodiments. The excerpted LED array 800 is analogous to that of FIG. 1I with the difference being one e-via 850 and one p-via 854 per pixel in addition to an off-centered n-via 852.

In FIG. 8, on the substrate 802 is a stack of semiconductor layers 804 comprising an n-type layer 804n, an active region 806 and a p-type layer 804p. A current spreading layer 811 is on the p-type layer 804p. N-via 852 comprises n-via spacer sidewall 832 which surrounds n-contact material 818n. A surface of the n-contact material 818n contacts the n-type layer 804n. An n-metal layer 836 is on a surface of the n-contact material 818n opposite that of the n-type layer 804n. A first hard mask layer 808 (of a first dielectric layer) is on the current spreading layer 811, and has been etched to form e-via 850. A guard layer 809 is on the first hard mask layer 808 and in a portion of the e-via 850 on its sidewall. A second hard mask layer 830 (of a second dielectric layer the same or different from that of the first dielectric material) is on the guard layer 809, and has been etched to form p-via 854 off-set from the e-via 850. A bottom surface of the p-via 854 contacts a top surface of the guard layer 809. In the p-via 354 is a p-metal material plug 316. On the p-metal material plug 316 and portions of the second hard mask layer 830 is a p-metal layer 834 that provides communication between the p-type layer 804b, the guard layer 809, and the p-metal material plug 816 to a p-contact material 818p. Trench spacers (or outer spacers) 814 insulate the p-contact material 818p from the n-type layer 804n and the active region 806. Inner spacers 812 are adjacent to the n-via spacer sidewall 832 and the trench spacers (or outer spacers) 814.

A passivation layer 820 is on the p-metal layer 834 and is between the n-metal layer 836 and the p-metal layer 834. An under bump metallization (UBM) material forms a cathode 824 in contact with the n-metal layer 836. The cathode 824 is sized as-appropriate for an array design. In this embodiment, the cathode 824 is not centered over the n-via 852.

In one or more embodiments of micro-LED dies and devices herein each of the plurality of spaced mesas include trenches therebetween results in a pixel pitch in a range of from 1 μm to 100 μm, including from 40 μm to 100 μm, 41 μm to 100 μm, and all values and subranges therebetween. In some embodiments, the pixel pitch is in a range of from 5 μm to 100 μm, 10 μm to 100 μm or 15 μm to 100 μm.

### Applications

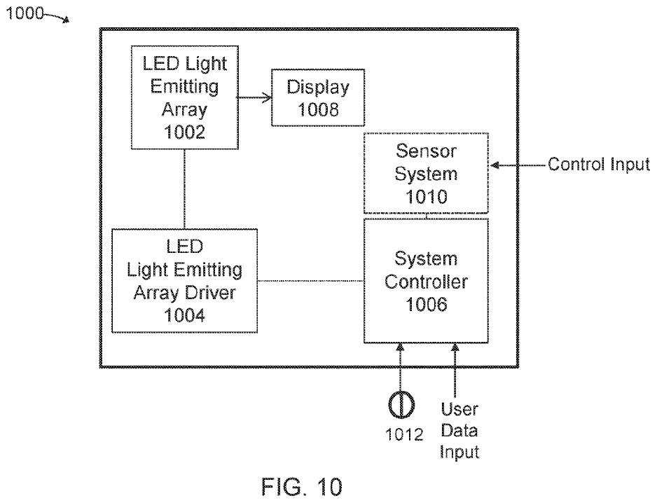

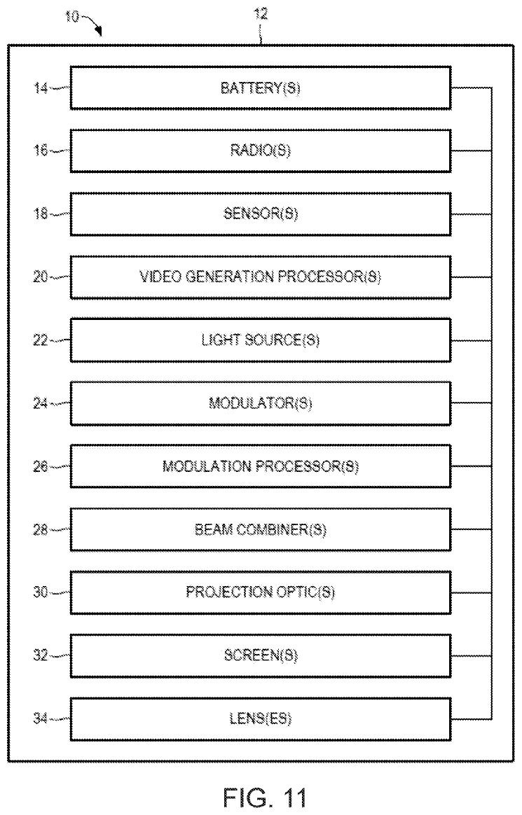

FIG. 10 schematically illustrates an exemplary display system 1000 utilizing LEDs, including uLEDs, disclosed herein. The display system 1000 comprises an LED light emitting array 1002 and display 1008 in electrical communication with an LED driver 1004. The display system 1000 also comprises a system controller 1006, such as a microprocessor. The controller 1006 is coupled to the LED driver 1004. The controller 1006 may also be coupled to the display 1008 and to optional sensor(s) 1010, and be powered by power source 1012. In one or more embodiments, user data input is provided to system controller 1006.

In one or more embodiments, the system is a camera flash system utilizing uLEDs. In such an embodiment, the LED light emitting array 1002 is an illumination array and lens system and the display 1008 comprises a camera, wherein the LEDs of 1002 and the camera of 1008 may be controlled by the controller 1006 to match their fields of view.

Optionally sensors 1010 with control input may include, for example, positional sensors (e.g., a gyroscope and/or accelerometer) and/or other sensors that may be used to determine the position, speed, and orientation of system. The signals from the sensors 1010 may be supplied to the controller 1006 to be used to determine the appropriate course of action of the controller 1006 (e.g., which LEDs are currently illuminating a target and which LEDs will be illuminating the target a predetermined amount of time later).

In operation, illumination from some or all of the pixels of the LED array in 1002 may be adjusted—deactivated, operated at full intensity, or operated at an intermediate intensity. As noted above, beam focus or steering of light emitted by the LED array in 1002 can be performed electronically by activating one or more subsets of the pixels, to permit dynamic adjustment of the beam shape without moving optics or changing the focus of the lens in the lighting apparatus.

LED array systems such as described herein may support various other beam steering or other applications that benefit from fine-grained intensity, spatial, and temporal control of light distribution. These applications may include, but are not limited to, precise spatial patterning of emitted light from pixel blocks or individual pixels. Depending on the application, emitted light may be spectrally distinct, adaptive over time, and/or environmentally responsive. The light emitting pixel arrays may provide pre-programmed light distribution in various intensity, spatial, or temporal patterns. Associated optics may be distinct at a pixel, pixel block, or device level. An example light emitting pixel array may include a device having a commonly controlled central block of high intensity pixels with an associated common optic, whereas edge pixels may have individual optics. In addition to flashlights, common applications supported by light emitting pixel arrays include video lighting, automotive headlights, architectural and area illumination, and street lighting.

Other applications of LED devices herein include augmented reality/virtual reality (AR/VR) systems, which may utilize uLEDs disclosed herein. One or more AR/VR systems include: augmented (AR) or virtual reality (VR) headsets, glasses, or projectors. Such AR/VR systems includes an LED light emitting array, an LED driver (or light emitting array controller), a system controller, an AR or VR display, a sensor system 810. Control input may be provided to the sensor system, while power and user data input is provided to the system controller. As will be understood, in some embodiments modules included in the AR/VR system can be compactly arranged in a single structure, or one or more elements can be separately mounted and connected via wireless or wired communication. For example, the light emitting array, AR or VR display, and sensor system can be mounted on a headset or glasses, with the LED driver and/or system controller separately mounted.

In one embodiment, the light emitting array can be used to project light in graphical or object patterns that can support AR/VR systems. In some embodiments, separate light emitting arrays can be used to provide display images, with AR features being provided by a distinct and separate micro-LED array. In some embodiments, a selected group of pixels can be used for displaying content to the user while tracking pixels can be used for providing tracking light used in eye tracking. Content display pixels are designed to emit visible light, with at least some portion of the visible band (approximately 400 nm to 750 nm). In contrast, tracking pixels can emit light in visible band or in the IR band (approximately 750 nm to 2,200 nm), or some combination thereof. As an alternative example, the tracking pixels could operate in the 800 to 1000 nanometer range. In some embodiments, the tracking pixels can emit tracking light during a time period that content pixels are turned off and are not displaying content to the user.

The AR/VR system can incorporate a wide range of optics in the LED light emitting array and/or AR/VR display, for example to couple light emitted by the LED light emitting array into AR/VR display as discussed above. For AR/VR applications, these optics may comprise nanofins and be designed to polarize the light they transmit.

In one embodiment, the light emitting array controller can be used to provide power and real time control for the light emitting array. For example, the light emitting array controller can be able to implement pixel or group pixel level control of amplitude and duty cycle. In some embodiments, the light emitting array controller further includes a frame buffer for holding generated or processed images that can be supplied to the light emitting array. Other supported modules can include digital control interfaces such as Inter-Integrated Circuit (12° C.) serial bus, Serial Peripheral Interface (SPI), USB-C, HDMI, Display Port, or other suitable image or control modules that are configured to transmit needed image data, control data or instructions.

In operation, pixels in the images can be used to define response of corresponding light emitting array, with intensity and spatial modulation of LED pixels being based on the image(s). To reduce data rate issues, groups of pixels (e.g. 5×5 blocks) can be controlled as single blocks in some embodiments. In some embodiments, high speed and high data rate operation is supported, with pixel values from successive images able to be loaded as successive frames in an image sequence at a rate between 30 Hz and 100 Hz, with 60 Hz being typical. Pulse width modulation can be used to control each pixel to emit light in a pattern and with an intensity at least partially dependent on the image.

In some embodiments, the sensor system can include external sensors such as cameras, depth sensors, or audio sensors that monitor the environment, and internal sensors such as accelerometers or two or three axis gyroscopes that monitor AR/VR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position. As another example, based on the one or more measurement signals from one or more gyroscope or position sensors that measure translation or rotational movement, an estimated position of AR/VR system relative to an initial position can be determined.

In some embodiments, the system controller uses data from the sensor system to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow.

Based on changes in position, orientation, or movement of the AR/VR system, the system controller can send images or instructions the light emitting array controller. Changes or modification in the images or instructions can also be made by user data input, or automated data input as needed. User data input can include but is not limited to that provided by audio instructions, haptic feedback, eye or pupil positioning, or connected keyboard, mouse, or game controller.

FIG. 13 shows a block diagram of an example of a visualization system 10. The visualization system 10 can include a wearable housing 12, such as a headset or goggles. The housing 12 can mechanically support and house the elements detailed below. In some examples, one or more of the elements detailed below can be included in one or more additional housings that can be separate from the wearable housing 12 and couplable to the wearable housing 12 wirelessly and/or via a wired connection. For example, a separate housing can reduce the weight of wearable goggles, such as by including batteries, radios, and other elements. The housing 12 can include one or more batteries 14, which can electrically power any or all of the elements detailed below. The housing 12 can include circuitry that can electrically couple to an external power supply, such as a wall outlet, to recharge the batteries 14. The housing 12 can include one or more radios 16 to communicate wirelessly with a server or network via a suitable protocol, such as WiFi.

The visualization system 10 can include one or more sensors 18, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 18 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 18 can capture a real-time video image of the surroundings proximate a user.

The visualization system 10 can include one or more video generation processors 20. The one or more video generation processors 20 can receive, from a server and/or a storage medium, scene data that represents a three-dimensional scene, such as a set of position coordinates for objects in the scene or a depth map of the scene. The one or more video generation processors 20 can receive one or more sensor signals from the one or more sensors 18. In response to the scene data, which represents the surroundings, and at least one sensor signal, which represents the location and/or orientation of the user with respect to the surroundings, the one or more video generation processors 20 can generate at least one video signal that corresponds to a view of the scene. In some examples, the one or more video generation processors 20 can generate two video signals, one for each eye of the user, that represent a view of the scene from a point of view of the left eye and the right eye of the user, respectively. In some examples, the one or more video generation processors 20 can generate more than two video signals and combine the video signals to provide one video signal for both eyes, two video signals for the two eyes, or other combinations.

The visualization system 10 can include one or more light sources 22 that can provide light for a display of the visualization system 10. Suitable light sources 22 can include a light-emitting diode, a monolithic light-emitting diode, a plurality of light-emitting diodes, an array of light-emitting diodes, an array of light-emitting diodes disposed on a common substrate, a segmented light-emitting diode that is disposed on a single substrate and has light-emitting diode elements that are individually addressable and controllable (and/or controllable in groups and/or subsets), an array of micro-light-emitting diodes (microLEDs), and others.

A light-emitting diode can be white-light light-emitting diode. For example, a white-light light-emitting diode can emit excitation light, such as blue light or violet light. The white-light light-emitting diode can include one or more phosphors that can absorb some or all of the excitation light and can, in response, emit phosphor light, such as yellow light, that has a wavelength greater than a wavelength of the excitation light.

The one or more light sources 22 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The visualization system 10 can include one or more modulators 24. The modulators 24 can be implemented in one of at least two configurations.

In a first configuration, the modulators 24 can include circuitry that can modulate the light sources 22 directly. For example, the light sources 22 can include an array of light-emitting diodes, and the modulators 24 can directly modulate the electrical power, electrical voltage, and/or electrical current directed to each light-emitting diode in the array to form modulated light. The modulation can be performed in an analog manner and/or a digital manner. In some examples, the light sources 22 can include an array of red light-emitting diodes, an array of green light-emitting diodes, and an array of blue light-emitting diodes, and the modulators 24 can directly modulate the red light-emitting diodes, the green light-emitting diodes, and the blue light-emitting diodes to form the modulated light to produce a specified image.

In a second configuration, the modulators 24 can include a modulation panel, such as a liquid crystal panel. The light sources 22 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 24 can include multiple modulation panels that can modulate different colors of light. For example, the modulators 24 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 24 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 10 can include one or more modulation processors 26, which can receive a video signal, such as from the one or more video generation processors 20, and, in response, can produce an electrical modulation signal. For configurations in which the modulators 24 directly modulate the light sources 22, the electrical modulation signal can drive the light sources 24. For configurations in which the modulators 24 include a modulation panel, the electrical modulation signal can drive the modulation panel.

The visualization system 10 can include one or more beam combiners 28 (also known as beam splitters 28), which can combine light beams of different colors to form a single multi-color beam. For configurations in which the light sources 22 can include multiple light-emitting diodes of different colors, the visualization system 10 can include one or more wavelength-sensitive (e.g., dichroic) beam splitters 28 that can combine the light of different colors to form a single multi-color beam.

The visualization system 10 can direct the modulated light toward the eyes of the viewer in one of at least two configurations. In a first configuration, the visualization system 10 can function as a projector, and can include suitable projection optics 30 that can project the modulated light onto one or more screens 32. The screens 32 can be located a suitable distance from an eye of the user. The visualization system 10 can optionally include one or more lenses 34 that can locate a virtual image of a screen 32 at a suitable distance from the eye, such as a close-focus distance, such as 500 mm, 750 mm, or another suitable distance. In some examples, the visualization system 10 can include a single screen 32, such that the modulated light can be directed toward both eyes of the user. In some examples, the visualization system 10 can include two screens 32, such that the modulated light from each screen 32 can be directed toward a respective eye of the user. In some examples, the visualization system 10 can include more than two screens 32. In a second configuration, the visualization system 10 can direct the modulated light directly into one or both eyes of a viewer. For example, the projection optics 30 can form an image on a retina of an eye of the user, or an image on each retina of the two eyes of the user.

### Embodiments

Various embodiments are listed below. It will be understood that the embodiments listed below may be combined with all aspects and other embodiments in accordance with the scope of the invention.

Embodiment (a) A light emitting diode (LED) die comprising: a plurality of pixels each having a sidewall and a top surface, and being defined by a mesa of semiconductor layers, each of the mesas including an n-type layer, an active region, and a p-type layer; a current spreading layer on the p-type layer of each of the pixels; a plurality of junction spacers comprising a spacer dielectric material conformal to the sidewall of each of the pixels; a first dielectric material on a portion of the current spreading layer of each of the pixels; a plurality of e-vias defined by e-via sidewalls of the first dielectric material, a guard layer on the first dielectric material and disposed in each of the e-vias in contact with the current spreading layer; a second dielectric material disposed on a portion of the guard layer of each of the pixels, insulating the n-type layers and the p-type layers of each of the pixels; a plurality of p-vias defined by p-via sidewalls of the second dielectric material, a p-metal material plug disposed in each of the p-vias in contact with the guard layer; a plurality of n-vias each defined by an n-via spacer sidewall of the spacer dielectric material that extend from a depth of the n-type layer of each of the pixels to an n-metal layer, an n-contact material disposed in each of the n-vias in contact with the n-type layer of each of the pixels; for each pixel, the n-metal layer being disposed on surfaces of the n-contact material, the n-via spacer sidewalls, and the second dielectric material, and in contact with a cathode; a plurality of p-contact materials disposed in trenches between the mesas; for each pixel, a p-metal layer being disposed on the p-metal material plug, the second dielectric material, the junction spacers, and the p-contact materials; a passivation layer comprising a passivation dielectric material disposed on the p-metal layer and optionally a portion of the n-metal layer of each of the pixels, and a portion of the second dielectric material, insulating the cathode of each of the pixels and the p-contact materials; and a common anode in communication with each of the p-contact materials.

Embodiment (b) The LED die of embodiment (a) comprising one n-via per pixel, one e-via per pixel, and two p-vias per pixel.

Embodiment (c) The LED die of embodiment (a) or (b), wherein plurality of pixels defines a matrix that is surrounded by the common anode.

Embodiment (d) The LED die of one of embodiments (a) to (c), wherein the junction spacers comprise: a plurality of trench spacers adjacent to the sidewall of each of the pixels, and inner spacers adjacent to each of the trench spacers and/or each of the n-via spacer sidewalls.

Embodiment (e) The LED die of one of embodiments (a) to (d), wherein a thickness of the mesa of semiconductor layers is in a range of from 1 μm to 10 μm.

Embodiment (f) The LED die of one of embodiments (a) to (e), wherein the first, second, spacer, and passivation dielectric materials independently comprise one or more of: silicon oxide (SiO), silicon dioxide (SiO₂), silicon nitride (SiN), silicon carbide (SiC), aluminum oxide (Al₂O₃), and aluminum nitride (AlN).

Embodiment (g) The LED die of one of embodiments (a) to (f), wherein the common anode, the p-contact materials, and the n-contact materials, comprise one or more of: copper (Cu), aluminum (AI), nickel (Ni), titanium (Ti), titanium-tungsten (TiW), silver (Ag), gold (Au), platinum (Pt), and palladium (Pd).

Embodiment (h) The LED die of one of embodiments (a) to (g), wherein the current spreading layer comprises indium tin oxide (ITO) and/or indium zinc oxide (IZO).

Embodiment (i) The LED die of one of embodiments (a) to (h), wherein the n-type layer comprises n-GaN and the p-type layer comprises p-GaN.

Embodiment (j) The LED die of one of embodiments (a) to (i), wherein the trench spacers span a longitudinal distance of greater than or equal to 95% of a thickness of the semiconductor layers.

Embodiment (k) The LED die of one of embodiments (a) to (j), wherein a pixel pitch of the mesas is in range of from 1 μm to 100 μm.

Embodiment (l) A light emitting diode (LED) device comprising: a source wafer comprising the light emitting diode (LED) die of one of embodiments (a) to (k); and a target wafer bonded to the source wafer.

Embodiment (m) The LED device of embodiment (l), wherein the target wafer is a complementary metal-oxide-semiconductor (CMOS) wafer.

Embodiment (n) The LED device of embodiment (l) or (m), wherein the target wafer comprises a substrate material selected from the group consisting of: ceramic, silicon, aluminum, a sapphire, silicon carbide, and III-nitride.

Embodiment (o) A method of manufacturing a light emitting diode (LED) die comprising: depositing a plurality of semiconductor layers including an n-type layer, an active region, and a p-type layer on a substrate; depositing a current spreading layer on the plurality of semiconductor layers; depositing a first hard mask layer comprising a first dielectric material on the current spreading layer; patterning the first hard mask layer to prepare e-vias defined by e-via sidewalls of the first dielectric material; depositing a guard layer on the first hard mask layer and in the e-vias; depositing a second hard mask layer comprising a second dielectric material on the guard layer; etching the substrate to form first trenches and expose positions of the current spreading layer; prepare inner spacers on sidewalls of the first trenches; etching the first trenches further to form extended trenches between mesas of the semiconductor layers and an n-via extending into each of the mesas; depositing a spacer dielectric material conformal to sidewalls of the extended trenches and the n-vias to prepare trench spacers and n-via spacer sidewalls, respectively; etching the second hard mask layer to prepare p-vias defined by p-via sidewalls of the second dielectric material; depositing a first electrode material in the extended trenches, the p-vias, and the n-vias, and planarizing the first electrode material to prepare p-contact materials, p-metal material plugs, n-contact materials; depositing a second electrode material on the substrate and patterning to prepare an n-metal layer in communication with the n-contact materials, and a p-metal layer in communication with the p-contact materials; preparing a common anode from a plurality of the p-contact materials, the common anode surrounding a plurality of pixels defined by the mesas; depositing a passivation layer comprising a passivation dielectric material on the substrate and patterning to dispose the passivation layer on the p-metal layers, optionally on a portion of the n-metal layers, a portion of the second dielectric material, insulating the n-type layer and p-type layer of each of the pixels; and preparing a cathode on each of the mesas.

Embodiment (p) The method of embodiment (o), wherein a thickness of each of the mesas of semiconductor layers is in a range of from 1 μm to 10 μm.

Embodiment (q) The method of embodiment (o) or (p), wherein the first, second, spacer, and passivation dielectric materials independently comprise one or more of: silicon oxide (SiO), silicon dioxide (SiO₂), silicon nitride (SiN), silicon carbide (SiC), aluminum oxide (Al₂O₃), and aluminum nitride (AlN).

Embodiment (r) The method of one of embodiments (o) to (q), wherein the common anode, the p-metal material plugs, the p-contact materials, and the n-contact materials, comprise one or more of: copper (Cu), aluminum (Al), nickel (Ni), titanium (Ti), titanium-tungsten (TiW), silver (Ag), gold (Au), platinum (Pt), and palladium (Pd).

Embodiment(s) The method of one of embodiments (o) to (r), wherein the current spreading layer comprises indium tin oxide (ITO) and/or indium zinc oxide (IZO).

Embodiment (t) The method of one of embodiments (o) to(s), wherein the n-type layer comprises n-GaN and the p-type layer comprises p-GaN.

Embodiment (u) The method of one of embodiments (o) to (t), wherein the trench spacers span a longitudinal distance of greater than or equal to 95% of a thickness of the semiconductor layers.

Embodiment (v) The method of one of embodiments (o) to (u), wherein a pixel pitch of the mesas is in range of from 5 μm to 100 μm.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A light emitting diode (LED) die comprising:
a plurality of pixels each having a sidewall and a top surface, and being defined by a mesa of semiconductor layers, each of the mesas including an n-type layer, an active region, and a p-type layer;
a current spreading layer on the p-type layer of each of the pixels;
a plurality of junction spacers comprising a spacer dielectric material conformal to the sidewall of each of the pixels;
a first dielectric material on a portion of the current spreading layer of each of the pixels;
a plurality of e-vias defined by e-via sidewalls of the first dielectric material, a guard layer on the first dielectric material and disposed in each of the e-vias in contact with the current spreading layer;
a second dielectric material disposed on a portion of the guard layer of each of the pixels, insulating the n-type layers and the p-type layers of each of the pixels;
a plurality of p-vias defined by p-via sidewalls of the second dielectric material, a p-metal material plug disposed in each of the p-vias in contact with the guard layer;
a plurality of n-vias each defined by an n-via spacer sidewall of the spacer dielectric material that extend from a depth of the n-type layer of each of the pixels to an n-metal layer, an n-contact material disposed in each of the n-vias in contact with the n-type layer of each of the pixels;
for each pixel, the n-metal layer being disposed on surfaces of the n-contact material, the n-via spacer sidewalls, and the second dielectric material, and in contact with a cathode;
a plurality of p-contact materials disposed in trenches between the mesas;
for each pixel, a p-metal layer being disposed on the p-metal material plug, the second dielectric material, the junction spacers, and the p-contact materials;
a passivation layer comprising a passivation dielectric material disposed on the p-metal layer and optionally a portion of the n-metal layer of each of the pixels, and a portion of the second dielectric material, insulating the cathode of each of the pixels and the p-contact materials; and
a common anode in communication with each of the p-contact materials.

2. The LED die of claim 1 comprising one n-via per pixel, one e-via per pixel, and two p-vias per pixel.

3. The LED die of claim 1, wherein plurality of pixels defines a matrix that is surrounded by the common anode.

4. The LED die of claim 1, wherein the junction spacers comprise: a plurality of trench spacers adjacent to the sidewall of each of the pixels, and inner spacers adjacent to each of the trench spacers and/or each of the n-via spacer sidewalls.

5. (canceled)

6. The LED die of claim 1, wherein the first, second, spacer, and passivation dielectric materials independently comprise one or more of: silicon oxide (SiO), silicon dioxide (SiO₂), silicon nitride (SiN), silicon carbide (SiC), aluminum oxide (Al₂O₃), and aluminum nitride (AlN).

7. The LED die of claim 1, wherein the common anode, the p-contact materials, and the n-contact materials, comprise one or more of: copper (Cu), aluminum (Al), nickel (Ni), titanium (Ti), titanium-tungsten (TiW), silver (Ag), gold (Au), platinum (Pt), and palladium (Pd).

8. The LED die of claim 1, wherein the current spreading layer comprises indium tin oxide (ITO) and/or indium zinc oxide (IZO).

9. The LED die of claim 1, wherein the n-type layer comprises n-GaN and the p-type layer comprises p-GaN.

10. The LED die of claim 1, wherein the trench spacers span a longitudinal distance of greater than or equal to 95% of a thickness of the semiconductor layers.

11. The LED die of claim 1, wherein a pixel pitch of the mesas is in range of from 1 μm to 100 μm.

12. A light emitting diode (LED) device comprising:
a source wafer comprising the light emitting diode (LED) die of claim 1; and
a target wafer bonded to the source wafer.

13. The LED device of claim 12, wherein the target wafer is a complementary metal-oxide-semiconductor (CMOS) wafer.

14. The LED device of claim 12, wherein the target wafer comprises a substrate material selected from the group consisting of: ceramic, silicon, aluminum, a sapphire, silicon carbide, and III-nitride.

15. A method of manufacturing the light emitting diode (LED) die of claim 1, the method comprising:
depositing the plurality of semiconductor layers including the n-type layer, the active region, and the p-type layer on the substrate;
depositing the current spreading layer on the plurality of semiconductor layers;
depositing a first hard mask layer comprising the first dielectric material on the current spreading layer;
patterning the first hard mask layer to prepare e-vias defined by e-via sidewalls of the first dielectric material;
depositing guard layer on the first hard mask layer and in the e-vias;
depositing a second hard mask layer comprising the second dielectric material on the guard layer;
etching the substrate to form first trenches and expose positions of the current spreading layer;
prepare inner spacers on sidewalls of the first trenches;
etching the first trenches further to form extended trenches between mesas of the semiconductor layers and the n-via extending into each of the mesas;
depositing the spacer dielectric material conformal to sidewalls of the extended trenches and the n-vias to prepare trench spacers and n-via spacer sidewalls, respectively;
etching the second hard mask layer to prepare p-vias defined by p-via sidewalls of the second dielectric material;
depositing the first electrode material in the extended trenches, the p-vias, and the n-vias, and planarizing the first electrode material to prepare p-contact materials, p-metal material plugs, n-contact materials;
depositing the second electrode material on the substrate and patterning to prepare an n-metal layer in communication with the n-contact materials, and the p-metal layer in communication with the p-contact materials;
preparing the common anode from the plurality of the p-contact materials, the common anode surrounding the plurality of pixels defined by the mesas;
depositing the passivation layer comprising the passivation dielectric material on the substrate and patterning to dispose the passivation layer on the p-metal layers, optionally on a portion of the n-metal layers, a portion of the second dielectric material, insulating the n-type layer and p-type layer of each of the pixels; and
preparing a cathode on each of the mesas.

16. (canceled)

17. The method of claim 15, wherein the first, second, spacer, and passivation dielectric materials independently comprise one or more of: silicon oxide (SiO), silicon dioxide (SiO₂), silicon nitride (SiN), silicon carbide (SiC), aluminum oxide (Al₂O₃), and aluminum nitride (AlN).

18. The method of claim 15, wherein the common anode, the p-metal material plugs, the p-contact materials, and the n-contact materials, comprise one or more of: copper (Cu), aluminum (Al), nickel (Ni), titanium (Ti), titanium-tungsten (TiW), silver (Ag), gold (Au), platinum (Pt), and palladium (Pd).

19. The method of claim 15, wherein the current spreading layer comprises indium tin oxide (ITO) and/or indium zinc oxide (IZO).

20. The method of claim 15, wherein the n-type layer comprises n-GaN and the p-type layer comprises p-GaN.

21. The method of claim 15, wherein the trench spacers span a longitudinal distance of greater than or equal to 95% of a thickness of the semiconductor layers.

22. The method of claim 15, wherein a pixel pitch of the mesas is in range of from 1 μm to 100 μm.
